(19) United States
(12) Patent Application Publication
(10) Pub. No.: US 2011/0140173 A1
(43) Pub. Date: Jun. 16, 2011

(54) Low OHMIC contacts containing germanium for gallium nitride or other nitride-based power devices

(75) Inventor: Jamal Ramdani, Scarborough, ME (US)

(73) Assignee: National Semiconductor Corporation, Santa Clara, CA (US)

(21) Appl. No.: 12/927,948

(22) Filed: Nov. 30, 2010

Related U.S. Application Data
(60) Provisional application No. 61/284,299, filed on Dec. 16, 2009.

(51) Int. Cl. H01L 29/66; H01L 21/20

(52) U.S. Cl. 257/194; 257/615; 438/478; 257/E29.166; 257/E21.09

(57) ABSTRACT

An apparatus includes a substrate, a Group III-nitride layer over the substrate, and an electrical contact over the Group III-nitride layer. The electrical contact includes a stack having multiple layers of conductive material, and at least one of the layers in the stack includes germanium. The layers in the stack may include a contact layer, where the contact layer includes aluminum copper. The stack could include a titanium or titanium alloy layer, an aluminum or aluminum alloy layer, and a germanium or germanium alloy layer. At least one of the layers in the stack could include an aluminum or titanium alloy having a germanium content between about 1% and about 5%.

### CROSS-REFERENCE TO RELATED APPLICATION AND PRIORITY CLAIM

This application claims priority under 35 U.S.C. §119(e) to U.S. Provisional Patent Application No. 61/284,299 filed on Dec. 16, 2009, which is hereby incorporated by reference.

### TECHNICAL FIELD

This disclosure relates generally to semiconductor devices. More specifically, this disclosure relates to low Ohmic contacts containing germanium for gallium nitride or other nitride-based power devices.

### BACKGROUND

Various Group III-V compounds are being investigated for use in high-power electronics applications. These compounds include “Group III-nitrides” such as gallium nitride (GaN), aluminum gallium nitride (AlGaN), and aluminum indium gallium nitride (AlInGaN). These compounds can be used to form High Electron Mobility Transistors (HEMTs) or other devices for use in high-power high-voltage applications.

High-performance HEMTs often require low and highly-stable specific contact resistances to the sources and drains of the transistors. Current Ohmic contacts to HEMTs often use titanium-aluminum-titanium-gold metal stacks, titanium-aluminum-titanium tungsten-gold metal stacks, or titanium-aluminum-molybdenum-gold metal stacks. Tungsten (W) and molybdenum (Mo) are practically insoluble in gold, making them excellent barriers to separate the gold (Au) and the aluminum (Al). This helps to prevent the formation of an aluminum auride (Al₂Au) phase, which can cause surface roughening and high resistivity. Titanium (Ti) and aluminum are often used in the formation of Ohmic contacts since they react with each other and with nitrogen to form titanium nitride (TiN) and titanium aluminum nitride (TiAlN) layers having low resistivity.

Recently, gallium nitride or aluminum gallium nitride layers have been heavily doped using silicon (Si) as a way to further reduce the specific contact resistance. However, implantations of this type often require very high temperature annealing (such as more than 1,200° C.) to activate the silicon donors in the gallium nitride or aluminum gallium nitride layers. Aluminum silicon alloys with a low silicon atomic fraction have also been used to reduce the specific resistance of a contact. During annealing, the silicon diffuses to the gallium nitride or aluminum gallium nitride layers and dopes these layers, thus reducing their specific contact resistance.

### BRIEF DESCRIPTION OF THE DRAWINGS

For a more complete understanding of this disclosure and its features, reference is now made to the following description, taken in conjunction with the accompanying drawings, in which:

FIG. 1 illustrates an example semiconductor structure having low Ohmic contacts for Group III-nitride devices according to this disclosure;

FIGS. 2A through 2E illustrate an example technique for forming a semiconductor structure having low Ohmic contacts for Group III-nitride devices according to this disclosure; and

FIG. 3 illustrates an example method for forming a semiconductor structure having low Ohmic contacts for Group III-nitride devices according to this disclosure.

### DETAILED DESCRIPTION

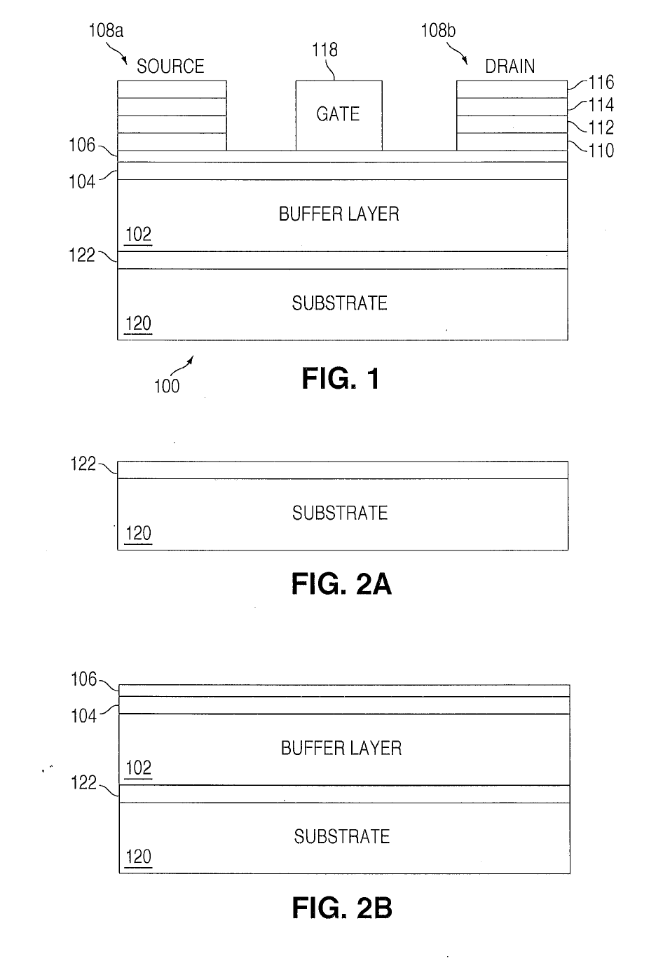

FIGS. 1 through 3, discussed below, and the various embodiments used to describe the principles of the present invention in this patent document are by way of illustration only and should not be construed in any way to limit the scope of the invention. Those skilled in the art will understand that the principles of the invention may be implemented in any type of suitably arranged device or system.

In general, this disclosure describes the use of germanium (Ge) and various germanium alloys, such as aluminum germanium (AlGe) and titanium germanium (TiGe), to improve Ohmic contacts for High Electron Mobility Transistors (HEMTs) and other Group III-nitride power devices. A “Group III-nitride” refers to a compound formed using nitrogen and at least one Group III element. Example Group III elements include indium, gallium, and aluminum. Example Group III-nitrides include gallium nitride (GaN), aluminum gallium nitride (AlGaN), indium aluminum nitride (InAlN), indium aluminum gallium nitride (InAlGaN), aluminum nitride (AlN), indium nitride (InN), and indium gallium nitride (InGaN). The inclusion of germanium in a stack of layers for an Ohmic contact can help to reduce the contact resistance to a Group III-nitride HEMT or other structure. This disclosure also describes the use of an aluminum copper (AlCu) contact layer instead of gold, which helps to avoid aluminum auride phase formation and provides a contact scheme comparable to silicon-based CMOS circuitry.

FIG. 1 illustrates an example semiconductor structure 100 having low Ohmic contacts for Group III-nitride devices according to this disclosure. In this example, the Ohmic contacts are used for electrical connections to a source and a drain of a Group III-nitride power transistor, such as an HEMT.

As shown in FIG. 1, the semiconductor structure 100 includes a buffer layer 102 and one or more barrier layers 104-106. Each of the buffer and barrier layers 102-106 could be formed from any suitable material(s). For example, the buffer layer 102 could be formed from gallium nitride, aluminum gallium nitride, or other Group III-nitride material(s). Also, each of the barrier layers 104-106 could be formed from gallium nitride, aluminum gallium nitride, or other Group III-nitride material(s), and different materials can be used in different barrier layers. For instance, the barrier layer 104 could represent a gallium nitride layer, and the barrier layer 106 could represent an aluminum gallium nitride layer. The aluminum concentration in an aluminum gallium nitride buffer layer could be much less than the aluminum concentration in an aluminum gallium nitride barrier layer. Each of the layers 102-106 could also be formed in any suitable manner. For example, each of the layers 102-106 could represent an epitaxial layer formed using a Metal-Organic Chemical Vapor Deposition (MOCVD) or Molecular Beam Epitaxy (MBE) technique.

One or more Ohmic contacts 108a-108b are formed over the barrier layer 106. In this example, each of the Ohmic contacts 108a-108b is formed by a stack of conductive layers 110-116. In general, the conductive layers 110-114 include at least one layer containing germanium or one or more germanium alloys, and the conductive layer 116 could include an aluminum copper alloy as a contact layer. As particular examples, the conductive layers 110-116 could form:
a titanium-aluminum germanium-titanium-aluminum copper stack;
an aluminum germanium-titanium-aluminum-aluminum copper stack;
a germanium-aluminum-titanium-aluminum copper stack;
a titanium-germanium-aluminum-aluminum copper stack;
a titanium germanium aluminum-aluminum-aluminum copper stack;
a titanium germanium-aluminum-aluminum copper stack; or
a titanium-aluminum germanium-aluminum-aluminum copper stack.
   These are provided as examples only. A wide variety of stacks that include germanium or some form of germanium alloy or compound can be used here. Also note that the use of four conductive layers is not required.

In particular embodiments, a copper content in an aluminum copper contact layer 116 could be between about 0.5% and about 1.0%, and the aluminum copper contact layer could be between about 100 nm and about 150 nm in thickness. Also, a titanium layer could be between about 10 nm and about 20 nm in thickness, a germanium layer could be between about 5 nm and about 15 nm in thickness, and a titanium germanium aluminum layer could be between about 10 nm and about 20 nm in thickness. Further, a titanium germanium layer could be between about 10 nm and about 20 nm in thickness, and an aluminum layer could be between about 50 nm and about 100 nm in thickness. Moreover, the germanium composition in any aluminum or titanium alloys could be between about 1% and about 5%. In addition, an aluminum germanium-based alloy could be used for n-type contacts since germanium is an n-type dopant to gallium nitride or aluminum gallium nitride.

The addition of copper (such as less than about 2% atomic weight) can be useful in reducing the rate of electro-migration and stress voiding. The reaction of germanium with copper on the top layer 116 could further reduce the contact resistance, enhance thermal stability, and reduce potential oxidation.

Each of the conductive layers 110-116 could be formed in any suitable manner. For example, the conductive layers 110-116 could be deposited on the barrier layer 106 using any suitable deposition technique, such as sputtering. The conductive layers 110-116 could then be etched, such as by using a photomask, to form the Ohmic contacts 108a-108b. However, any other suitable technique could be used to form the Ohmic contacts 108a-108b.

A gate contact 118 is also formed over the barrier layer 106. The gate contact 118 represents the gate of a HEMT or other Group III-nitride device. The gate contact 118 could be formed using any suitable conductive material(s) and in any suitable manner. The gate contact 118 could, for example, be formed by masking the Ohmic contacts 108a-108b and depositing and etching conductive materials(s) to form the contact 118.

The buffer layer 102 here could be formed over other layers and structures. For example, the buffer layer 102 could be formed over a substrate 120 and one or more intervening layers 122. The substrate 120 represents any suitable semiconductor structure on which other layers or structures are formed. For example, the substrate 120 could represent a silicon <111>, sapphire, silicon carbide, or other semiconductor substrate. The substrate 120 could also have any suitable size and shape, such as a wafer between three and twelve inches in diameter (although other sizes could be used). The intervening layers 122 could include any suitable layer(s) providing any suitable functionality. For instance, the intervening layers 122 could include a nucleation layer and one or more thermal management layers.

In FIG. 1, the use of germanium can have great potential as a high dopant of one or more Group III-nitride layers and can therefore further reduce contact resistance. Theoretically, germanium is predicted to be an excellent donor in nitrogen-rich atmospheres, and its solubility in gallium nitride can exceed 1E21/cm³ as long as the aluminum mole fraction in aluminum gallium nitride is lower than 30%.

Although FIG. 1 illustrates one example of a semiconductor structure 100 having low Ohmic contacts for Group III-nitride devices, various changes may be made to FIG. 1. For example, while specific materials and manufacturing processes are described above, any other materials and manufacturing processes could be used to form various layers or other structures of the semiconductor structure 100. Also, while specific sizes or dimensions have been described, each layer or other component of the semiconductor structure 100 could have any suitable size, shape, and dimensions.

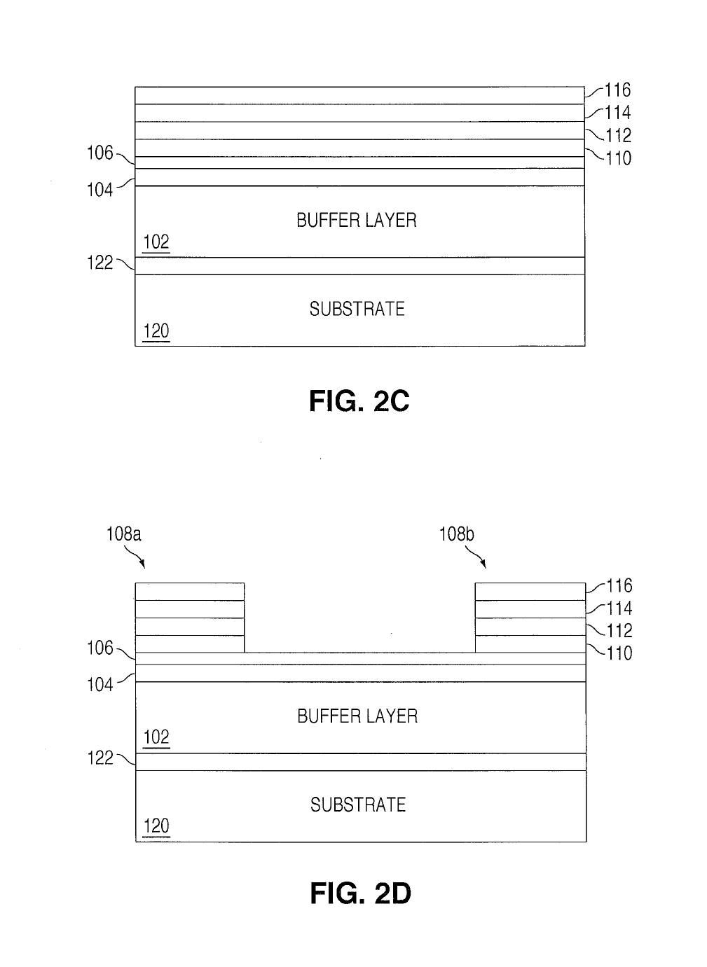

FIGS. 2A through 2E illustrate an example technique for forming a semiconductor structure having low Ohmic contacts for Group III-nitride devices according to this disclosure. As shown in FIG. 2A, one or more intervening layers 122 are formed over a substrate 120. The intervening layers 122 could include any number of layers, each formed from any suitable material(s). For instance, the intervening layers 122 could include a thermal stress management layer formed from one or more Group III-nitride materials. As particular examples, the thermal stress management layer could be formed using a combination of aluminum gallium nitride layers with different gallium concentrations. A low-temperature aluminum nitride layer can be inserted into the thermal stress management layer. Other configurations of the thermal stress management layer could also be used, such as those including super-lattice structures of aluminum nitride/aluminum gallium nitride (multiple thin layers each a few nanometers thick). The thermal stress management layer could have a minimum of two layers, and those layers can be repeated two, three, or more times. The intervening layers 122 could also be formed using any suitable technique, depending on the material(s) being formed. Example techniques can include physical vapor deposition (PVD), chemical vapor deposition (CVD), plasma-enhanced CVD (PECVD), MOCVD, or MBE.

As shown in FIG. 2B, a buffer layer 102 and one or more barrier layers 104-106 are formed over the structure. Each of the buffer and barrier layers 102-106 can be formed from any suitable material(s) and in any suitable manner. For example, each of the buffer and barrier layers 102-106 can be formed from one or more epitaxial Group III-nitride layers.

As shown in FIG. 2C, multiple conductive layers 110-116 are formed over the barrier layer 106. Each of the conductive layers 110-114 could be formed from any suitable material(s), and at least one of the layers 110-114 includes germanium. Also, the conductive layer 116 could be formed from aluminum copper.

In some embodiments, the layers 110-116 can be formed using deposition by sputtering at temperatures between room temperature (RT) and about 300° C. The fabrication process could include a pre-deposition etching using argon (Ar+) ions to reduce or eliminate surface contaminants such as carbon and organic residues, as well as to obtain a good metal adhesion. Alloying can be used and can be carried out in a rapid thermal annealing system, such as at temperatures between about 700° C. and about 1,000° C. in a nitrogen atmosphere for a period of about thirty seconds to one minute. In particular embodiments, a two-step annealing process can be used. The first step can be carried out at lower temperatures, such as less than about 750° C., to diffuse a germanium layer into one or more gallium nitride or aluminum gallium nitride layers. The second step can be a high temperature anneal, such as up to about 900° C. for about thirty seconds, to form an aluminum titanium nitride eutectic responsible for the Ohmic contacts to gallium nitride or aluminum gallium nitride. The diffusion of germanium in the gallium nitride/aluminum gallium nitride layers can heavily dope these layers and further reduce the contact resistance.

As shown in FIG. 2D, the conductive layers 110-116 are etched or otherwise processed to form the Ohmic contacts 108a-108b. Each of the Ohmic contacts 108a-108b could have any suitable size and shape, and different Ohmic contacts 108a-108b could have different sizes or shapes. The Ohmic contacts 108a-108b could be formed in any suitable manner. For example, a layer of photoresist material could be deposited over the conductive layers 110-116 and patterned to create openings through the photoresist material. An etch could then be performed to etch the conductive layers 110-116 through the openings in the photoresist material.

As shown in FIG. 2E, the gate contact 118 is formed over the conductive layers 110-116. The gate contact 118 could be formed using any suitable conductive material(s) and in any suitable manner. For example, the Ohmic contacts 108a-108b could be covered using a mask, and conductive material(s) can be deposited between the Ohmic contacts 108a-108b and etched to form the gate contact 118.

At some point during this process, one or more of the layers 102-106 could be further processed to form structures used in HEMTs or other Group III-nitride devices. For example, implantations, diffusions, or other processing operations could be performed to form doped source and drain regions of a transistor in one or more of the layers 102-106. Other or additional processing steps could be performed to form structures for other or additional Group III-nitride devices.

Although FIGS. 2A through 2E illustrate one example of a technique for forming a semiconductor structure having low Ohmic contacts for Group III-nitride devices, various changes may be made to FIGS. 2A through 2E. For example, while specific materials and processing techniques are described above, each layer or other component of the structure could be formed from any suitable material(s) and in any suitable manner.

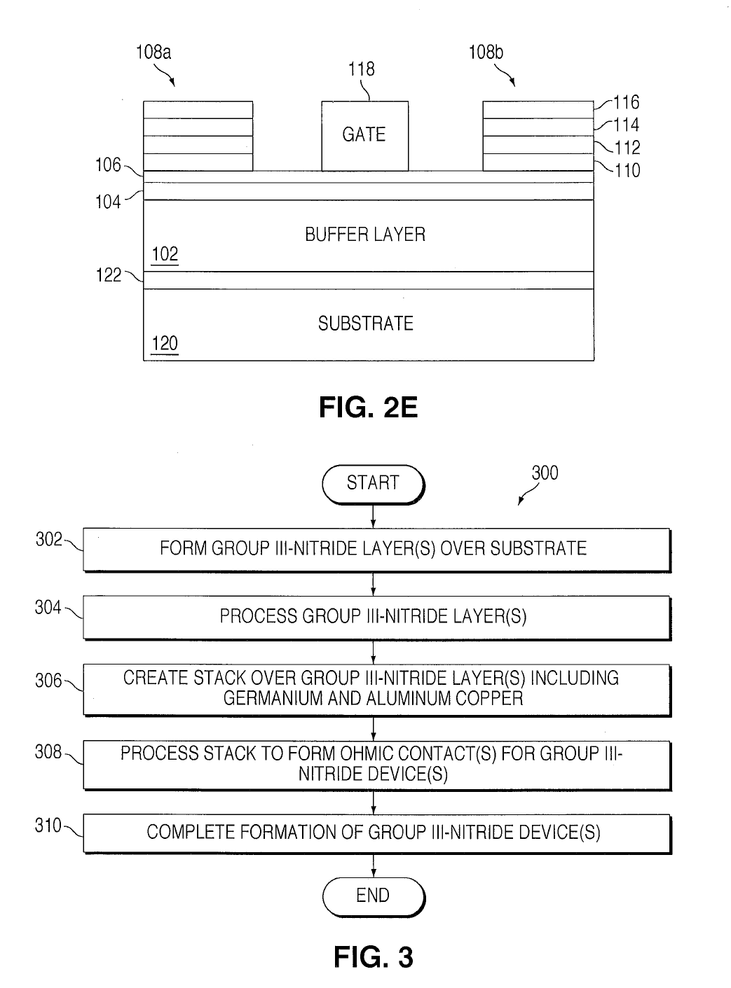

FIG. 3 illustrates an example method 300 for forming a semiconductor structure having low Ohmic contacts for Group III-nitride devices according to this disclosure. As shown in FIG. 3, one or more Group III-nitride layers are formed over a substrate at step 302. This could include, for example, forming a nucleation layer, thermal stress management layer(s), buffer layer, and barrier layer(s) over the substrate 102. One or more of these layers could be omitted, however, depending on the implementation. At least one Group III-nitride material can be used in at least one layer during this step, such as in one or more Group III-nitride epitaxial layers. The one or more Group III-nitride layers are processed at step 304. This could include, for example, doping portions of at least one Group III-nitride layer to form source and drain regions of a transistor. However, any other or additional processing steps could be performed here.

A conductive stack is created over the one or more Group III-nitride layers at step 306. This could include, for example, depositing different conductive layers 110-116 over the barrier layer(s), such as conductive layers having aluminum or titanium. At least one of the conductive layers 110-114 includes germanium, and the contact layer 116 could include aluminum copper. The conductive stack is processed to form one or more Ohmic contacts for one or more Group III-nitride devices at step 308. This could include, for example, etching the conductive stack to form Ohmic contacts 108a-108b. The Ohmic contacts 108a-108b could be in electrical contact with the source and drain regions of a transistor or other structures of one or more Group III-nitride devices.

At this point, formation of one or more Group III-nitride devices could be completed at step 310. This could include, for example, forming a gate contact 118 over the barrier layer(s). This could complete the formation of one or more Group III-nitride HEMTs or other structures.

Although FIG. 3 illustrates one example of a method 300 for forming a semiconductor structure having low Ohmic contacts for Group III-nitride devices, various changes may be made to FIG. 3. For example, while shown as a series of steps, various steps in FIG. 3 could overlap, occur in parallel, or occur in a different order.

It may be advantageous to set forth definitions of certain words and phrases that have been used within this patent document. The terms “include” and “comprise,” as well as derivatives thereof, mean inclusion without limitation. The term “or” is inclusive, meaning and/or.

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. An apparatus comprising:
a substrate;
a Group III-nitride layer over the substrate; and
an electrical contact over the Group III-nitride layer, the electrical contact comprising a stack having multiple layers of conductive material, at least one of the layers in the stack comprising germanium.

2. The apparatus of claim 1, wherein the layers in the stack include a contact layer, the contact layer comprising aluminum copper.

3. The apparatus of claim 2, wherein:
the contact layer has a copper content between about 0.5% and about 1.0%; and
the contact layer has a thickness between about 100 nm and about 150 nm.

4. The apparatus of claim 1, wherein the stack comprises:
a titanium or titanium alloy layer;
an aluminum or aluminum alloy layer; and
a germanium or germanium alloy layer.

5. The apparatus of claim 1, wherein at least one of the layers in the stack comprises an aluminum or titanium alloy having a germanium content between about 1% and about 5%.

6. The apparatus of claim 1, wherein the Group III-nitride layer comprises a buffer layer and at least one barrier layer, the buffer and barrier layers comprising Group III-nitride epitaxial layers.

7. The apparatus of claim 1, wherein:
the electrical contact comprises one of multiple electrical contacts; and
the apparatus further comprises a gate contact between the electrical contacts.

8. A system comprising:
a semiconductor structure comprising a substrate and a Group III-nitride layer over the substrate;
a Group III-nitride integrated circuit device in or over the Group III-nitride layer; and
multiple electrical contacts in electrical connection to the Group III-nitride integrated circuit device, each electrical contact comprising a stack having multiple layers of conductive material, at least one of the layers in the stack comprising germanium.

9. The system of claim 8, wherein the Group III-nitride integrated circuit device comprises a Group III-nitride high electron mobility transistor (HEMT).

10. The system of claim 8, wherein the layers in the stack include a contact layer, the contact layer comprising aluminum copper.

11. The system of claim 10, wherein:
the contact layer has a copper content between about 0.5% and about 1.0%; and
the contact layer has a thickness between about 100 nm and about 150 nm.

12. The system of claim 8, wherein the stack comprises:
a titanium or titanium alloy layer;
an aluminum or aluminum alloy layer; and
a germanium or germanium alloy layer.

13. The system of claim 8, wherein at least one of the layers in the stack comprises an aluminum or titanium alloy having a germanium content between about 1% and about 5%.

14. The system of claim 8, wherein the Group III-nitride layer comprises a buffer layer and at least one barrier layer, the buffer and barrier layers comprising Group III-nitride epitaxial layers.

15. The system of claim 8, wherein the Group III-nitride integrated circuit device further comprises a gate contact between the electrical contacts.

16. A method comprising:
forming a Group III-nitride layer over a substrate; and
forming an electrical contact over the Group III-nitride layer, the electrical contact comprising a stack having multiple layers of conductive material, at least one of the layers in the stack comprising germanium.

17. The method of claim 16, further comprising:
forming a Group III-nitride integrated circuit device using the Group III-nitride layer, the electrical contact in electrical connection to the Group III-nitride integrated circuit device.

18. The method of claim 16, wherein the layers in the stack include a contact layer, the contact layer comprising aluminum copper.

19. The method of claim 18, wherein:
the contact layer has a copper content between about 0.5% and about 1.0%; and
the contact layer has a thickness between about 100 nm and about 150 nm.

20. The method of claim 16, wherein at least one of the layers in the stack comprises an aluminum or titanium alloy having a germanium content between about 1% and about 5%.
